(19) United States
(12) Patent Application Publication
(10) Pub. No.: US 2006/0137613 A1
(43) Pub. Date: Jun. 29, 2006

(54) Plasma generating apparatus, plasma generating method and remote plasma processing apparatus

(76) Inventor: Shigeru Kasai, Yamanashi-Ken (JP)

Correspondence Address: SMITH, GAMBRELL & RUSSELL, LLP, 1850 M STREET, N.W., SUITE 800, WASHINGTON, DC, 20036, US

(21) Appl. No.: 10/545,399

(22) PCT Filed: Feb. 13, 2004
(86) PCT No.: PCT/JP04/01533

§ 371 Date: Aug. 12, 2005

(30) Foreign Application Priority Data
Jan. 27, 2004 (JP) 2004-018012

(51) Int. Cl. C23C 16/00

(52) U.S. Cl. 118/723 MW; 118/723 ME

(57) ABSTRACT

A compact plasma generating apparatus providing high efficiency of plasma excitation is presented. A plasma generating apparatus (100) comprises a microwave generating apparatus (10) for generating microwaves, a coaxial waveguide (20) having a coaxial structure comprising an inner tube (20a) and an outer tube (20b), a monopole antenna (21) being attached to one end of said inner tube (20a), for directing the microwaves generated by said microwave generating apparatus (10) to the monopole antenna (21), a resonator (22) composed of dielectric material for holding the monopole antenna (21), and a chamber (23) in which a specific process gas is fed for plasma excitation. The chamber (23) has an open surface and the resonator (22) is placed on this open surface, and the process gas is excited by the microwaves radiated from the monopole antenna (21) through the resonator (22) into the interior of the chamber (23) to generate plasma.

### BACKGROUND OF THE INVENTION

1. Field of the Invention

The present invention relates to a plasma generating apparatus which excites a specific process gas by microwaves, a plasma generating method, and a remote plasma processing apparatus which processes an object to be processed by the excited process gas.

2. Background Art

In the manufacturing process of semiconductor devices or liquid crystal displays, a plasma processing apparatus, such as a plasma etching apparatus and plasma CVD apparatus, is used for plasma processing, such as etching and film formation, on a substrate to be processed, such as a semiconductor wafer and glass substrate.

A known plasma generating method using a remote plasma processing apparatus is realized by a remote plasma applicator having: a plasma tube made of dielectric material through which a process gas is flown; a waveguide aligned perpendicular to this plasma tube; and a coolant tube wound spirally around a portion of the plasma tube (hereinafter referred to as a “gas excitation portion”) which is located inside the waveguide and exposed to microwaves (e.g., refer to Japanese patent laid-open application publication 219295/1997). Due to heat generated by the gas excitation portion of the plasma tube, in this remote plasma applicator, a coolant is circulated through the coolant tube.

In suchlike remote plasma applicator, however, the part inside the plasma tube used to excite a process gas is limited, and furthermore the coolant tube attached to the gas excitation portion interrupts the microwave transmission into the plasma tube, thus causing a problem that improvement of the plasma excitation efficiency is difficult to achieve. Although the plasma excitation efficiency can be improved with less winding of the coolant tube around the gas excitation portion, then the gas excitation portion cannot be sufficiently cooled down while the risk of the coolant tube breakage increases.

In addition, suchlike remote plasma applicator has poor space efficiency, thus resulting in a problem of increasing the whole size of the apparatus, due to the structure in which the plasma tube and the waveguide are perpendicular to each other.

### SUMMARY OF THE INVENTION

The present invention is made in view of the above circumstances, and the object thereof is to provide a plasma generating apparatus that has high efficiency of plasma excitation. Another purpose of the present invention is to provide a compact plasma generating apparatus that has good space efficiency. Yet another purpose of the present invention is to provide a remote plasma processing apparatus comprising such plasma generating apparatus.

The present invention provides a plasma generating apparatus comprising: a microwave generating apparatus for generating microwaves with a predetermined wavelength; a coaxial waveguide having a coaxial structure comprising an inner tube and an outer tube, an antenna being attached to one end of said inner tube, for directing the microwaves generated by said microwave generating apparatus to said antenna; a resonator composed of dielectric material for holding said antenna; and a chamber in which a specific process gas is fed for plasma excitation, said chamber having an open surface, said resonator being placed on said open surface, wherein said process gas is excited by the microwaves radiated from said antenna through said resonator into the interior of said chamber. Impedance matching in the coaxial waveguide is performed by a slug tuner which is provided slidably in a longitudinal direction of the coaxial waveguide. As for the antenna to be used, various kinds can be included, such as a monopole antenna, helical antenna, slot antenna, etc. In the event that a monopole antenna is used, when λa is a wavelength of the microwaves generated by the microwave generating apparatus, εr is a relative dielectric constant of the resonator, and λg is a wavelength of the microwaves inside the resonator obtained by dividing the wavelength λa by the square root of the relative dielectric constant εr (λ=λa/εr^{1/2}), it is preferable that the length of the monopole antenna is approximately 25% of the wavelength λg, and the thickness of the resonator is approximately 50% of the wavelength λg. In the event that a helical antenna is used, it is preferable that the thickness of the resonator, between the end of the helical antenna and a surface of the resonator on the chamber side, is approximately 25% of the wavelength λg.

In the event that a slot antenna is used, it is preferable that the thickness of the resonator is approximately 25% of the wavelength λg. In the event that one antenna is used, a plasma generating apparatus to be used preferably has a microwave power source, an amplifier for regulating output power of the microwaves which are output from this microwave power source, and an isolator for absorbing reflected microwaves which are returning to the amplifier after being output from the amplifier. On the contrary, a plurality of the coaxial waveguide and antenna can be provided in the plasma generating apparatus. In this case, a microwave generating apparatus to be used preferably has a microwave power source, a distributor for distributing the microwaves generated by this microwave power source to each of the coaxial waveguide and antenna, a plurality of amplifiers for regulating output power of microwaves respectively which are output from the distributor, and a plurality of isolators for absorbing reflected microwaves which are returning to the plurality of amplifiers after being output from the plurality of amplifiers.

Preferable material for the resonator is quartz-type material, single-crystal-alumina-type material, polycrystalline-alumina-type material or aluminum-nitride-type material. It is preferable that a corrosion protection member composed of quartz-type material, single-crystal-alumina-type material or polycrystalline-alumina-type material is applied on the inner surface of the chamber to prevent corrosion of the chamber.

The chamber preferably has a jacket structure with cooling ability by flowing a coolant in the interior of the members constituting the chamber. In this manner the chamber can be easily cooled down. The chamber also preferably comprises a base-enclosed cylindrical member having said open surface at one end. To efficiently excite a process gas by microwaves, an exhaust vent is formed in the bottom wall of the base-enclosed cylindrical member to discharge the gas excited by microwaves outwardly from the chamber, and a gas discharge opening is formed in the proximity of the open surface side of the side wall of the base-enclosed cylindrical member to discharge the process gas to the interior space.

In a plasma generating apparatus, the impedance is high before plasma ignition, which fact may cause total reflection of microwaves. For this reason, in a plasma generating apparatus comprising a plurality of antennas, when microwaves are radiated from all antennas for plasma generation, the microwaves radiated from these antennas are combined to produce high-power microwaves, which turn back to each of the antennas. In such situations, an additional problem arises that it is necessary for each antenna to increase the size of a circulator and dummy load which constitute the isolator to protect the amplifiers from such high-power microwaves.

To solve the new problem, the present invention provides a plasma generating method in a plasma generating apparatus comprising a plurality of antennas for radiating microwaves of a predetermined output level to a chamber in which a process gas is fed for plasma excitation, the method comprising the steps of: generating plasma by radiating microwaves from one or some of said plurality of antennas into the interior of said chamber to excite said process gas; and stabilizing the plasma by radiating microwaves from all of said plurality of antennas into the interior of said chamber after the plasma generation.

To generate plasma in this way in a plasma generating apparatus comprising a plurality of antennas, a plasma generating apparatus comprising a plasma control device may be used for controlling the microwave generating apparatus, wherein microwaves are radiated from one or some of the plurality of antennas through the resonator into the interior of the chamber to excite said process gas and, after the plasma generation, microwaves are radiated from all of the plurality of antennas through the resonator into the interior of the chamber.

The present invention further provides a remote plasma processing apparatus comprising the above plasma generating apparatus. That is, a remote plasma processing apparatus comprising: a plasma generating apparatus for exciting a specific process gas by microwaves; and a substrate processing chamber for accommodating a substrate and providing specific processing to said substrate by the excited gas generated by exciting said process gas in said plasma generating apparatus, said plasma generating apparatus comprising: a microwave generating apparatus for generating microwaves with a predetermined wavelength; a coaxial waveguide having a coaxial structure comprising an inner tube and an outer tube, an antenna being attached to one end of said inner tube, for directing the microwaves generated by said microwave generating apparatus to said antenna; a resonator composed of dielectric material for holding said antenna; and a chamber in which a specific process gas is fed to be excited by the microwaves radiated from said antenna through said resonator for plasma excitation is provided.

The plasma generating apparatus according to the present invention can improve plasma excitation efficiency because the microwave transmission and radiation efficiencies are high and the microwaves radiated from the resonator pass through without any interruption to excite a process gas within the whole interior space of the chamber. In this manner, the whole size of the plasma generating apparatus can be reduced. Such high efficiency also can reduce the amount of a process gas to be used, thereby reducing the running cost. Furthermore, proper configuration settings for the antenna and the resonator can facilitate the generation of standing waves in the resonator, and thus stable plasma can be generated by the microwaves uniformly radiated from the resonator to the chamber.

In the event that a plurality of antennas are comprised, the advantageous point is that the size of the amplifiers or the like can be reduced wherein small isolators can prevent the damage of the amplifiers caused by the reflected microwaves by using one or some of the antennas for plasma ignition. Furthermore, in the remote plasma processing apparatus according to the present invention, the size reduction of the plasma generating apparatus permits greater latitude in the space utility of the remote plasma processing apparatus, thus reducing the whole size of the remote plasma processing apparatus.

### BRIEF DESCRIPTION OF THE DRAWINGS

FIG. 1 is a cross-sectional view showing a schematic structure of a plasma generating apparatus.

FIG. 2A is an explanatory drawing showing plasma generation conditions as a result of simulation of a resonator having a thickness D which is greater than FIG. 2B.

FIG. 2B is an explanatory drawing showing plasma generation conditions as a result of simulation of a resonator having a thickness D which is greater than FIG. 2C.

FIG. 2C is an explanatory drawing showing plasma generation conditions as a result of simulation of a resonator having a thickness D of approximately A g₂/2.

FIG. 3 is a cross-sectional view showing a schematic structure of another plasma generating apparatus.

FIG. 4 is a cross-sectional view showing a schematic structure of yet another plasma generating apparatus.

FIG. 5A is a cross-sectional view showing a schematic structure of yet another plasma generating apparatus.

FIG. 5B is a plan view showing disposition of monopole antennas with respect to a resonator of the plasma generating apparatus shown in FIG. 5A.

FIG. 6A is a cross-sectional view showing a schematic structure of yet another plasma generating apparatus.

FIG. 6B is a plan view showing disposition of helical antennas with respect to a resonator of the plasma generating apparatus shown in FIG. 6A.

FIG. 7A is a cross-sectional view showing a schematic structure of yet another plasma generating apparatus.

FIG. 7B is a plan view showing division pattern of slot antennas shown in FIG. 7A.

FIG. 8 is an explanatory diagram showing a control system of a plasma generating apparatus which controls a microwave generating apparatus.

FIG. 9 is a cross-sectional view showing a schematic structure of a plasma etching apparatus.

### DETAILED DESCRIPTION OF THE INVENTION

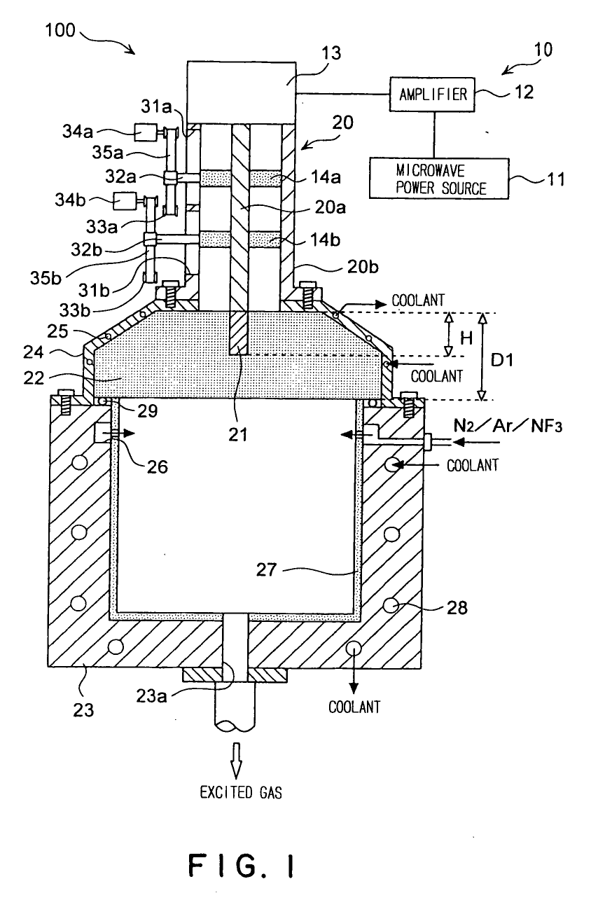

The embodiments of the present invention are described below in detail with reference to the drawings. FIG. 1 is a cross-sectional view showing a schematic structure of a plasma generating apparatus 100. The plasma generating apparatus 100 broadly has a microwave generating apparatus 10, a coaxial waveguide 20 comprising an inner tube 20a and an outer tube 20b, a monopole antenna 21 attached to the end of the inner tube 20a, a resonator 22 and a chamber 23.

The microwave generating apparatus 10 has a microwave power source 11 such as magnetron which generates microwaves of 2.45 GHz frequency for example, an amplifier 12 which regulates the microwaves generated by the microwave power source 11 to a predetermined output level, an isolator 13 which absorbs the reflected microwaves which are output from the amplifier 12 and returning to the amplifier 12, and slug tuners 14a and 14b which are attached to the coaxial waveguide 20. One end of the coaxial waveguide 20 is attached to the isolator 13.

The isolator 13 has a circulator and a dummy load (coaxial terminator) wherein the microwaves trying to travel from the monopole antenna 21 back to the amplifier 12 are directed to the dummy load by the circulator, and the microwaves directed by the circulator is converted to heat by the dummy load.

Slits 31a and 31b are formed in the outer tube 20b of the coaxial waveguide 20 in a longitudinal direction. The slug tuner 14a is connected to a lever 32a which is inserted in the slit 31a, and the lever 32a is secured to a part of a belt 35a suspended between a pulley 33a and a motor 34a. As in the same manner, the slug tuner 14b is connected to a lever 32b which is inserted in the slit 31b, and the lever 32b is secured to a part of a belt 35b suspended between a pulley 33b and a motor 34b.

The slug tuner 14a can be slid in a longitudinal direction of the coaxial waveguide 20 by driving the motor 34a, and the slug tuner 14b can be slid in a longitudinal direction of the coaxial waveguide 20 by driving the motor 34b. Such independent adjustment of the slug tuners 14a and 14b allows impedance matching for the monopole antenna 21, thus reducing the microwaves reflected from the monopole antenna 21. The slits 31a and 31b are sealed by belt sealing mechanism or the like, not shown, to prevent leakage of the microwaves from the slits 31a and 31b.

Given that λa is the wavelength of the microwaves generated by the microwave generating apparatus 10, εr₁ is the relative dielectric constant of the material constituting the slug tuners 14a and 14b, and λg₁ is the wavelength obtained by dividing the wavelength λa by the square root of the relative dielectric constant εr₁ (εr₁^{1/2}) (λg₁=λa/εr^{1/2}, i.e. the wavelength of the microwaves inside the slug tuners 14a and 14b), the thickness of the slug tuners 14a and 14b is to be approximately 25% (¼ wavelength) of the wavelength λg₁.

The monopole antenna 21 attached to one end of the inner tube 20a has a rod shape (columnar) and is buried in the resonator 22 to be held. The resonator 22 is held by a cover 24 and, as will hereinafter be described, occludes the open surface (upper surface) of the chamber 23 when the cover 24 is attached to the chamber 23.

The microwaves radiated from the monopole antenna 21 generate standing waves in the resonator 22. In this way the microwaves are radiated uniformly to the chamber 23. The cover 24 connected to the outer tube 20b of the coaxial waveguide 20 to cover the upper and side surfaces of the resonator 22 is composed of metal material in order to prevent microwave radiation from escaping from the upper and side surfaces of the resonator 22. The resonator 22 generates heat due to the standing waves excited therein. To suppress the temperature rise of the resonator 22, a coolant passage 25 is provided in the cover 24 for circulating a coolant (e.g. cooling water). The coolant can be used in a manner that a cooling circulation apparatus, not shown, circulates the coolant.

A dielectric material is used for the resonator 22 and a material that exhibits excellent corrosion resistance against the excited gas generated in the chamber 23 is suitable. Such examples include quartz-type material (quartz, molten quartz, quartz glass, etc.), single-crystal-alumina-type material (sapphire, alumina glass, etc.), polycrystalline-alumina-type material and aluminum-nitride-type material.

Given that λa is the wavelength of the microwaves generated by the microwave generating apparatus 10, εr₂ is the relative dielectric constant of the resonator 22, and λg₂ is the wavelength obtained by dividing the wavelength λa by the square root of the relative dielectric constant εr₂ (εr₂^{1/2}) (λg₂=λa/εr₂^{1/2}, i.e. the wavelength of the microwaves inside the resonator 22), the length (height) H of the monopole antenna 21 is to be 25% (¼ wavelength) of the wavelength λg₂ and the thickness (D1) of the resonator 22 is to be 50% (½ wavelength) of the wavelength λg₂ in order to facilitate the generation of standing microwaves in the resonator 22.

This comes mainly from the following reason. That is, in the event that the length of the monopole antenna 21 is λg₂/4, the generated electric field intensity is at a maximum at the end of the monopole antenna 21. If at this point the thickness of the resonator 22 is λg₂/2, the electric field intensity is zero (0) at the boundary between the lower surface of the resonator 22 (the surface on the side of the chamber 23) and the chamber 23, and thus the microwaves are not reflected even if the dielectric constant of the resonator 22 and that of vacuum are different. The magnetic field intensity at this boundary surface is at a maximum on the other hand, and again the microwaves are not reflected if the magnetic permeability of the resonator 22 is the same as that of vacuum. Note that quartz-type material, single-crystal-alumina-type material, polycrystalline-alumina-type material and aluminum-nitride-type material used for the resonator 22 are non-magnetic substance whose relative magnetic permeability is approximately 1.0 that is the same as the magnetic permeability of vacuum. Consequently the microwaves are radiated to the chamber 23 efficiently.

The chamber 23 has base-enclosed cylindrical shape and is generally composed of metal material such as stainless, aluminum, etc. By attaching the cover 24 on the upper surface of the chamber 23, the upper surface opening of the chamber 23 is occluded by the resonator 22. Numeral 29 in FIG. 1 is a seal ring. In the proximity of the upper surface of the side wall of the chamber 23, a gas discharge opening 26 is formed for discharging a specific process gas (e.g. N₂, Ar, NF₃, etc.) delivered from a gas feeding device, not shown, into the interior space of the chamber 23.

The process gas discharged from the gas discharge opening 26 into the interior space of the chamber 23 is excited by the microwaves radiated from the monopole antenna 21 through the resonator 22 into the interior space of the chamber 23 to generate plasma. The excited gas generated in this way is discharged outwardly (e.g. to a processing chamber accommodating a substrate) from an exhaust vent 23a formed in the bottom wall of the chamber 23.

In order to suppress the temperature rise of the chamber 23 due to heat generated by the process gas excitation caused by microwaves, a jacket structure having cooling ability is provided wherein a coolant passage 28 is formed in the chamber 23, as in the cover 24, to flow a coolant within the chamber 23. On the inner surface of the chamber 23, a corrosion protection member 27 composed of quartz-type material, single-crystal-alumina-type material or polycrystalline-alumina-type material is applied to prevent corrosion caused by the excited gas.

In the plasma generating apparatus 100 with such a structure, firstly cooling water flows through the cover 24 and the chamber 23 so that the temperatures of the resonator 22 and the chamber 23 do not rise excessively. Then the microwave generating apparatus 10 is driven for the microwave power source 11 to generate microwaves of a predetermined frequency, and after that the amplifier 12 amplifies the microwaves to a predetermined output level. The microwaves adjusted to a predetermined output level by the amplifier 12 are delivered to the monopole antenna 21 through the isolator 13 and the coaxial waveguide 20. At this point the slug tuners 14a and 14b are driven to perform impedance matching to reduce microwave reflection from the monopole antenna 21.

The microwaves radiated from the monopole antenna 21 generate standing waves inside the resonator 22. In this way the microwaves are radiated from the resonator 22 uniformly into the interior of the chamber 23. With these setups, a process gas is fed into the interior of the chamber 23 and excited by the microwaves to generate plasma. The excited gas produced in this way is delivered through the exhaust vent 23a to a chamber, not shown, which accommodates an object to be processed such as a substrate for example.

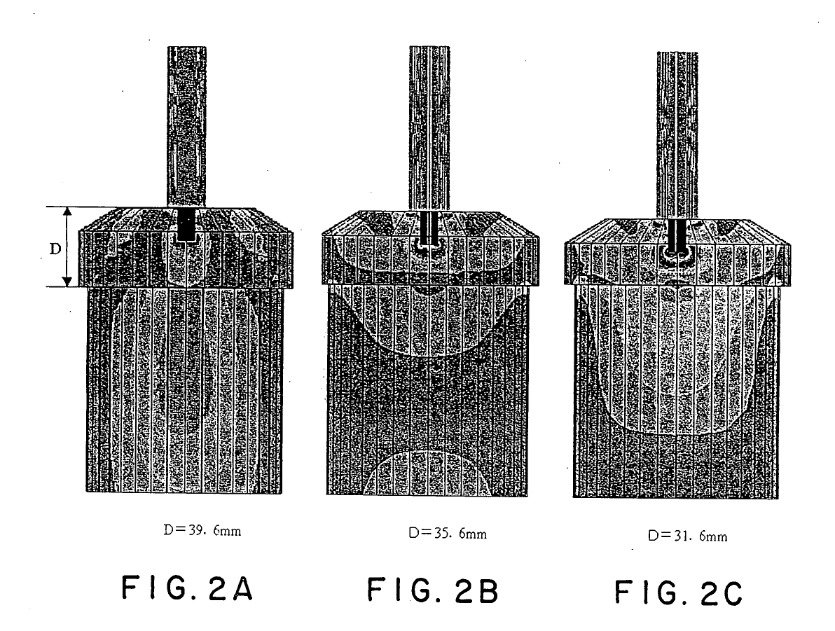

FIG. 2 is an explanatory drawing showing the results of correlation simulation between the thickness (D) of the resonator 22 and plasma generation conditions. At this point, the frequency of the microwaves generated by the microwave generating apparatus 10 is set at 2.45 GHz (i.e. the wavelength λa is approximately 122 mm) and the resonator 22 is made of crystalline quartz. The relative dielectric constant of crystalline quartz is approximately 3.75, and the wavelength λg₂ of the microwaves inside the resonator 22 thus is approximately 63.00 mm. The length of the monopole antenna 21 is approximately λg₂/4 (=15.75 mm).

In FIG. 2C, the thickness D of the resonator 22 is approximately λg₂/2. The best efficiency is expected with the resonator 22 having a thickness of λg₂/2 assuming an infinite parallel plate. In consideration of practical size and shape, however, the reflection in the case of the resonator 22 having a thickness of λg₂/2 is approximately 58%, which is not very efficient. Given such parameters, the thickness of the resonator 22 is increased as shown in FIG. 2B to FIG. 2A. When the thickness of the resonator 22 is 35.6 mm (as in FIG. 2B), the reflection is approximately 22%, and when the thickness of the resonator 22 is 39.6 mm (as in FIG. 2A), the reflection is approximately 6%, showing progress in efficiency. Evidently, increased thickness of the resonator 22 in actual designing of antennas can yield a good result relative to the theoretical figure.

As stated above, the thickness of the resonator 22 for providing high efficiency in an actual apparatus is different from the theoretical figure because the resonator 22 is not an infinite parallel plate. The optimal thickness of the resonator 22 can be confirmed by simulation in which the length (height) H of the monopole antenna 21 is 23-26% of the wavelength λg₂ and the thickness (D1) of the resonator 22 is 50-70% of the wavelength λg₂.

In the plasma generating apparatus 100, as stated above, plasma can be generated uniformly within the whole interior space of the chamber 23 so that a process gas can be efficiently excited. Moreover, there is no need to intersect the supply line of a process gas with waveguide as in a conventional plasma generating apparatus so that the size of the plasma generating apparatus 100 itself can be reduced.

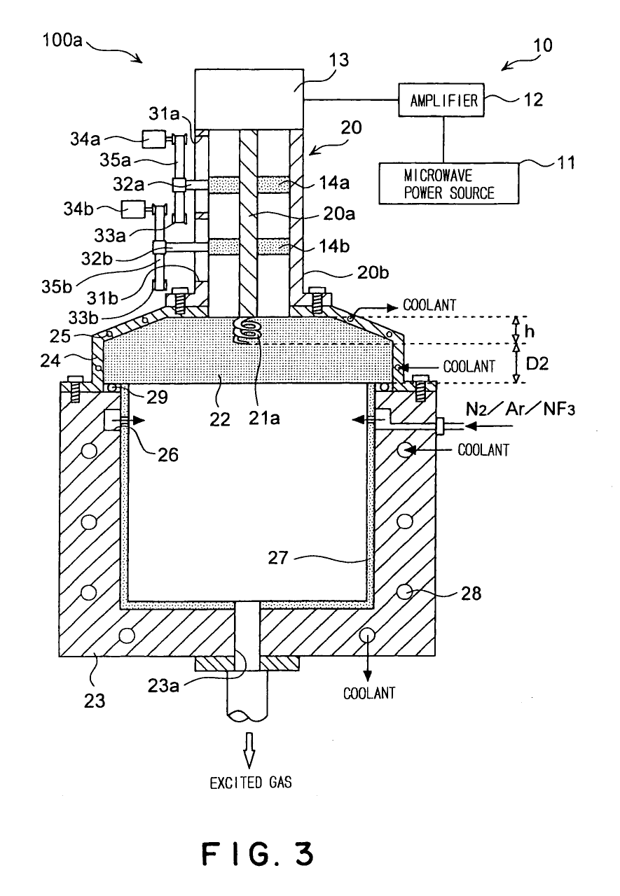

In the next place another embodiment of a plasma generating apparatus will be explained. FIG. 3 is a cross-sectional view showing a schematic structure of a plasma generating apparatus 100a. The difference between the plasma generating apparatus 100a and the plasma generating apparatus 100 illustrated in FIG. 1 as explained above is that a helical antenna 21a is attached to the end of the inner tube 20a of the coaxial waveguide 20 and is buried in the resonator 22.

In the event that the helical antenna 21a is used, the whole length of the helical antenna 21a is to be 25% of the wavelength λg₂ (¼ wavelength), and thereby the generated electric field intensity is at a maximum at the end of the helical antenna 21a. The thickness (D2) of the resonator 22, between the end of the helical antenna 21a and the lower surface of the resonator 22, is to be 25% of the wavelength λg₂ (¼ wavelength), and thereby the electric field intensity is zero (0) at the boundary between the lower surface of the resonator 22 and the chamber 23, and thus the microwaves are not reflected even if the dielectric constant of the resonator 22 and that of vacuum are different. The magnetic field intensity at this boundary surface is at a maximum on the other hand, and again the microwaves are not reflected if the magnetic permeability of the resonator 22 is the same as that of vacuum.

In the event that the helical antenna 21a is used, the linear length (height) h of the helical antenna 21a is shorter than the overall length. Consequently the thickness of the whole resonator 22 is h+approximately λg₂/4, and the thickness of the resonator 22 can thus be reduced compared to the thickness in which the monopole antenna 21 is used. In this case, again, the thickness of the resonator 22 for providing high efficiency in an actual apparatus is different from the theoretical figure because the resonator 22 is not an infinite parallel plate. The optimal thickness of the resonator 22 can be confirmed by simulation in which the length of the helical antenna 21a is 23-26% of the wavelength λg₂ and the thickness (D2) of the resonator 22 is 25-45% of the wavelength λg₂.

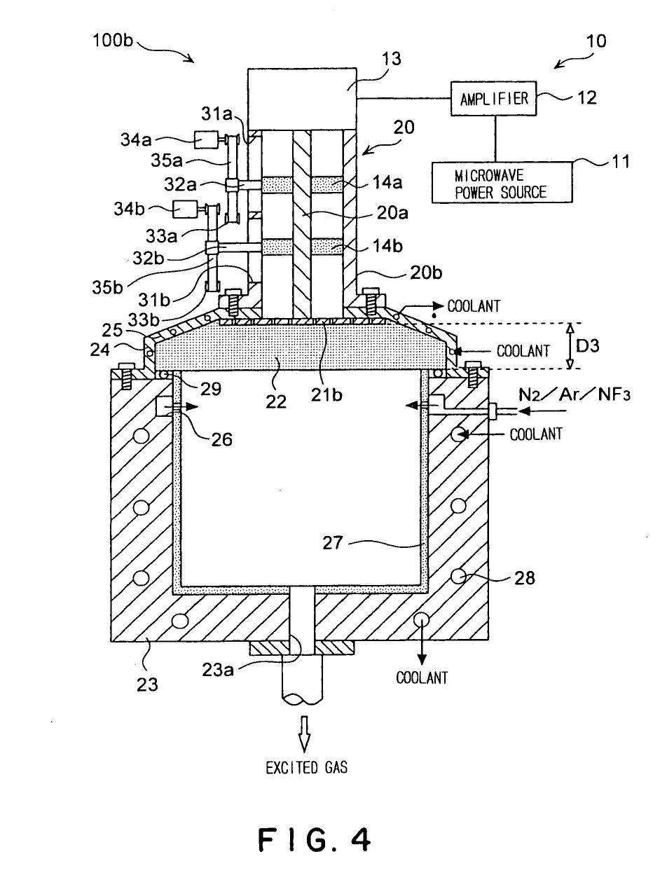

FIG. 4 is a cross-sectional view showing a schematic structure of a plasma generating apparatus 100b. The difference between the plasma generating apparatus 100b and the plasma generating apparatus 100 illustrated in FIG. 1 as explained above is that a slot antenna 21b is attached to the end of the inner tube 20a of the coaxial waveguide 20 and is buried in the resonator 22 to be held.

The slot antenna 21b has a structure, for example, that arc-shaped slots (holes) with a predetermined width are formed concentrically in a metal disc. In the event that the slot antenna 21b is used, the thickness (between the lower surface of the slot antenna 21b and the lower surface of the resonator 22) D3 of the resonator 22 is to be 25% of the wavelength λg₂ (¼ wavelength). When the slot antenna 21b is used, the generated electric field intensity is at a maximum at the lower surface of the slot antenna 21b. The electric field intensity is zero (0) at the boundary between the lower surface of the resonator 22 and the chamber 23, and thus the microwaves are not reflected even if the dielectric constant of the resonator 22 and that of vacuum are different. The magnetic field intensity at this boundary surface is at a maximum on the other hand, and again the microwaves are not reflected if the magnetic permeability of the resonator 22 is the same as that of vacuum. In this case, again, the thickness of the resonator 22 for providing high efficiency in an actual apparatus is different from the theoretical figure because the resonator 22 is not an infinite parallel plate. The optimal thickness of the resonator 22 can be confirmed by simulation in which the thickness (D3) of the resonator 22 is 25-45% of the wavelength λg₂ when the slot antenna 21b is used.

By forming the slot antenna 21b thinly, the total thickness of the slot antenna 21b and the resonator 22 together can be thinner relative to the thickness in which the monopole antenna 21 or helical antenna 21a is used. In the event that the monopole antenna 21 is used, however, although the thickness of the resonator 22 is increased, the advantages include simple structure, low cost and high efficiency of plasma excitation, compared to the utilization of the helical antenna 21a or the slot antenna 21b.

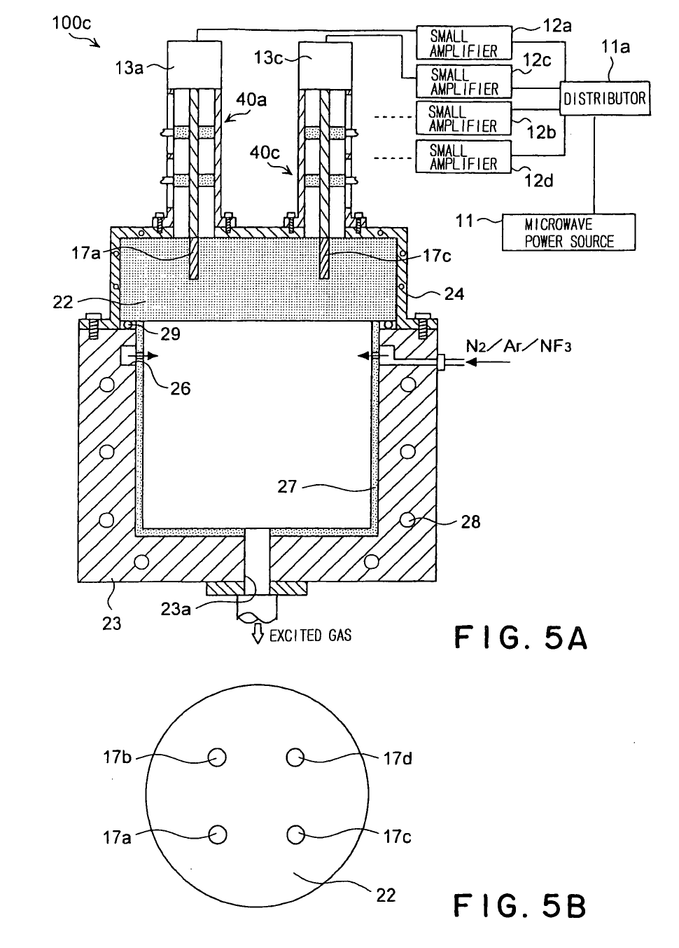

Although the above explanation involves the cases with one antenna, a remote plasma processing apparatus comprising the plasma generating apparatus 100 occasionally requires 500 W or above level of electric power for microwave output. In this case, a plurality of small amplifiers are comprised instead of the amplifier 12 shown in FIG. 1 and the output power from those small amplifiers are combined to realize high output power. In this connection, a plurality of antennas may be provided corresponding to the number of the small amplifiers, whereby microwaves are transmitted from each small amplifier to each antenna using a coaxial waveguide, as shown as plasma generating apparatuses 100c-100e in FIGS. 5-7.

FIG. 5A is a cross-sectional view of a schematic structure of the plasma generating apparatus 100c, and FIG. 5B is a plan view showing disposition of monopole antennas 17a-17d with respect to the resonator 22. The microwaves that are output from the microwave power source 11 are distributed to plural destinations (FIGS. 5A and 5B show a case of 4 distributions) by a distributor 11a. Each of the microwaves that is output from the distributor 11a is input into small amplifiers 12a-12d where the microwaves are amplified to a predetermined output level. The microwaves that is output from each of the small amplifiers 12a-12d are delivered to the monopole antennas 17a-17d provided in the resonator 22 through isolators 13a-13d (the isolators 13b and 13d are located behind the isolators 13a and 13c respectively and thus not shown) and coaxial waveguides 40a-40d (the coaxial waveguides 40b and 40d are located behind the coaxial waveguides 40a and 40c respectively and thus not shown). The microwaves radiated from each of the monopole antennas 17a-17d generate standing waves inside the resonator 22, and the microwaves are radiated from the resonator 22 into the interior of the chamber 23. Note that each of the coaxial waveguides 40a-40d has the same structure as the coaxial waveguide 20.

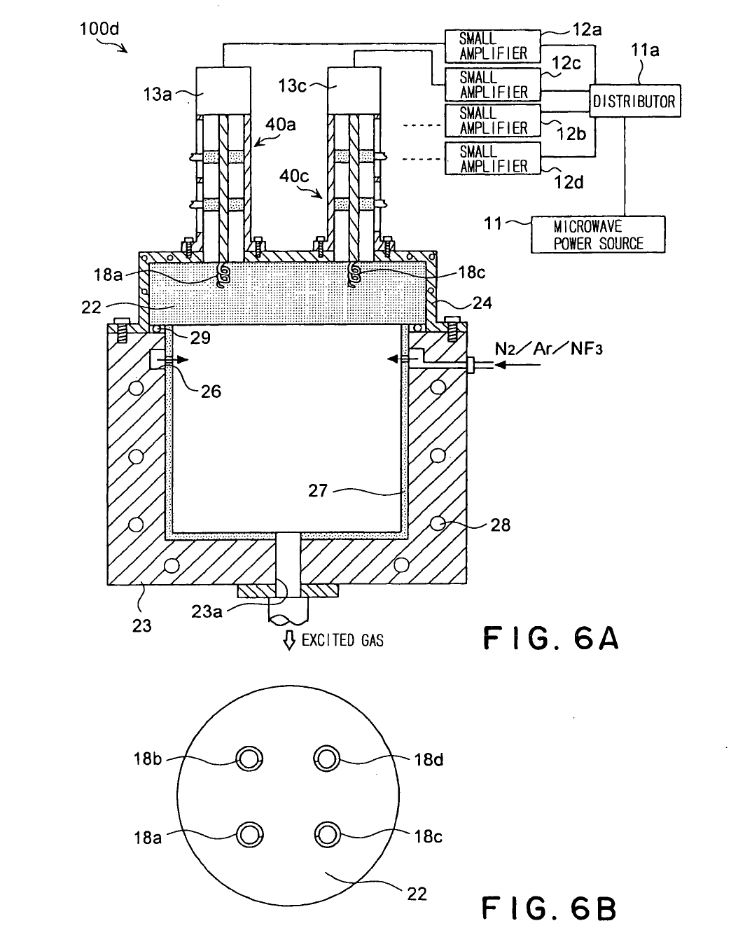

FIG. 6A is a schematic cross-sectional view of a plasma generating apparatus 100d, and FIG. 6B is a plan view showing disposition of helical antennas 18a-18d with respect to the resonator 22. The structure of the plasma generating apparatus 100d is the same as the plasma generating apparatus 100c shown in FIGS. 5A and 5B except that the monopole antennas 17a-17d included in the plasma generating apparatus 100c are replaced by the helical antennas 18a-18d.

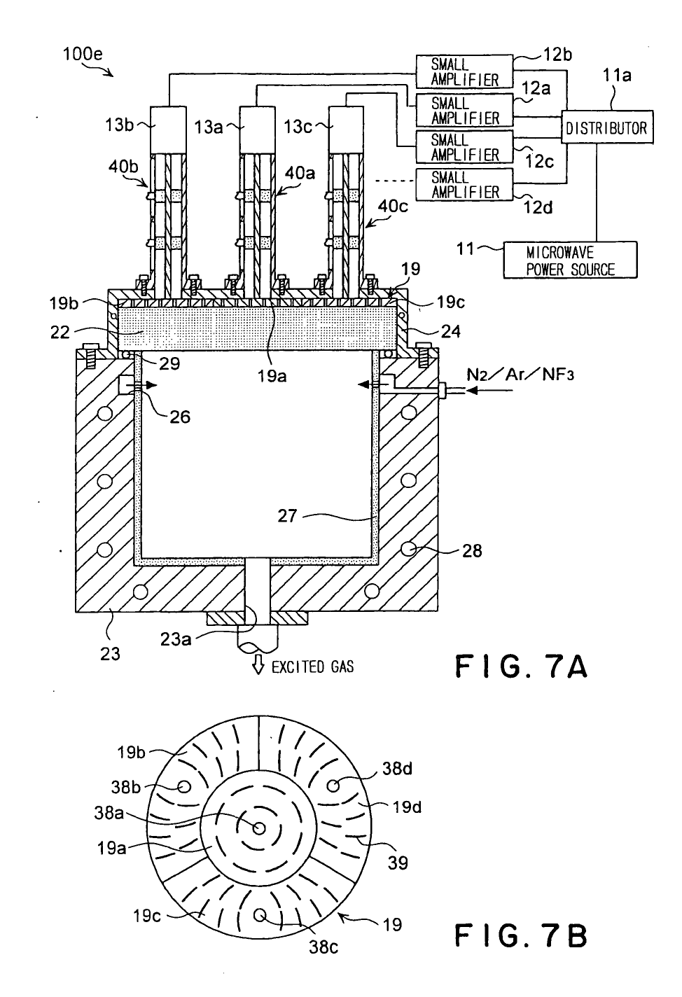

FIG. 7A is a schematic cross-sectional view of a plasma generating apparatus 100e, and FIG. 7B is a plan view showing division pattern of slot antenna 19. The slot antenna 19 included in the plasma generating apparatus 100e is divided into 4 blocks 19a-19d by a metal plate, and in the blocks 19a-19d, feeding points 38a-38d are provided respectively to attach the coaxial waveguides 40a-40d (the coaxial waveguide 40d is located behind the coaxial waveguide 40a and thus not shown). In each of the blocks 19a-19d, slots 39 (hole portions) are formed in a pattern, corresponding to the location where each of the feeding points 38a-38d is provided.

Such plasma generating apparatuses 100c-100e can realize lower cost of the amplifiers and higher efficiency of plasma excitation that can improve plasma uniformity.

In the above plasma generating apparatuses 100 and 100a-100e, for the meantime, the impedance is high before plasma ignition and becomes low and stable thereafter. Prior to plasma ignition, the total reflection of microwaves radiated from the antenna may occur resulting from the high impedance.

There is only one antenna 20 in the plasma generating apparatus 100, and the isolator 13 to be used therefore only requires the compatibility with the output power of the microwaves that the antenna 20 can radiate, and the same applies to the plasma generating apparatuses 100a and 100b.

In the plasma generating apparatus 100c comprising a plurality of antennas, however, when microwaves are radiated from all 4 monopole antennas 17a-17d for plasma generation, the microwaves radiated from these 4 monopole antennas 17a-17d are combined to produce high-power microwaves, which turn back to each of the small amplifiers 12a-12d. It is disadvantageous to increase the size of circulators and dummy loads which constitute the isolators 13a-13d to protect the small amplifiers 12a-12d from such high-power microwaves, in terms of the apparatus cost saving and downsizing. The problem also applies to the plasma generating apparatuses 100d and 100e.

As a method to limit the increase of the size of the isolators 13a-13d and to protect the small amplifiers 12a-12d, a plasma control device may be used for controlling the microwave generating apparatus 10 to stabilize the plasma wherein microwaves are radiated from one or some of the antennas 17a-17d through the resonator 22 into the interior of the chamber 23 to excite a process gas and, after the plasma generation, microwaves are radiated from all the antennas 17a-17d through the resonator 22 into the interior of the chamber 23.

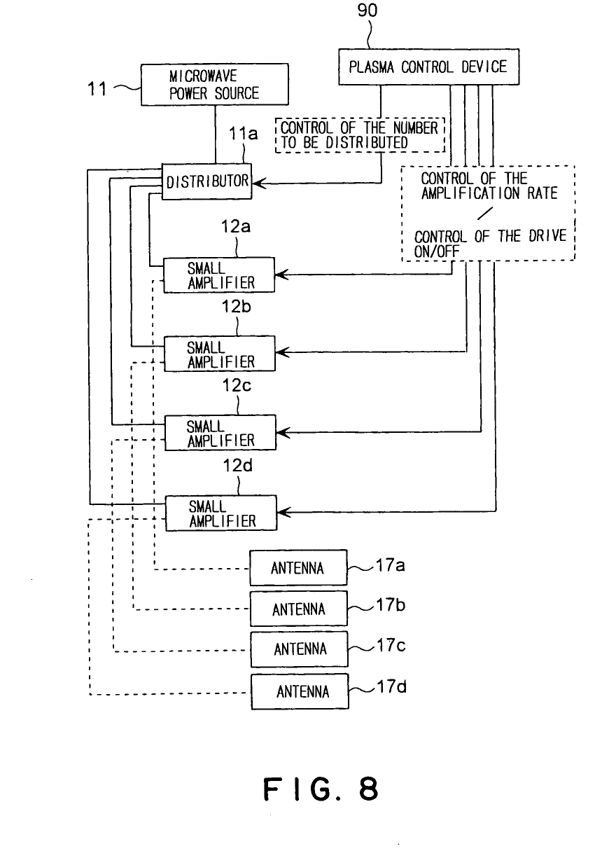

To be more precise, a plasma control device 90 serves for controlling at least either the number to be distributed by the distributor 11a or the number of the small amplifiers 12a-12d that are to be driven, as shown in FIG. 8. For example, the plasma control device 90 allows the distributor 11a to distribute the microwaves that are output from the microwave power source 11 in 4 portions to be input to the small amplifiers 12a-12d respectively, but only the small amplifier 12a is driven and the microwaves are not amplified by the other small amplifiers 12b-12d. In this manner the microwaves are substantially radiated solely from the antenna 17a prior to the plasma ignition. After the plasma ignition, the plasma control device 90 serves to drive all the small amplifiers 12a-12d to radiate microwaves from all the antennas 17a-17d. The plasma can be stabilized in this manner.

Moreover, the plasma control device 90 serves to input the microwaves that are output from the microwave power source 11 to the small amplifier 12a without distributing at the distributor 11a and amplify the microwaves that are input to the small amplifier 12a at a predetermined amplification rate to be output. As a result, microwaves can be radiated solely from the antenna 17a prior to the plasma ignition. After the plasma ignition as a consequence, the plasma control device 90 performs the distribution of the microwaves at the distributor 11a so that the microwaves are input to all the small amplifiers 12a-12d and drives all the small amplifiers 12a-12d. In this manner microwaves are radiated from all the antennas 17a-17d and the plasma can be stabilized.

In this connection, the number of the antennas to radiate microwaves for plasma ignition is not limited to 1 but may be 2 or more as long as the increase of the size of circulators and dummy loads which constitute the isolators is tolerable.

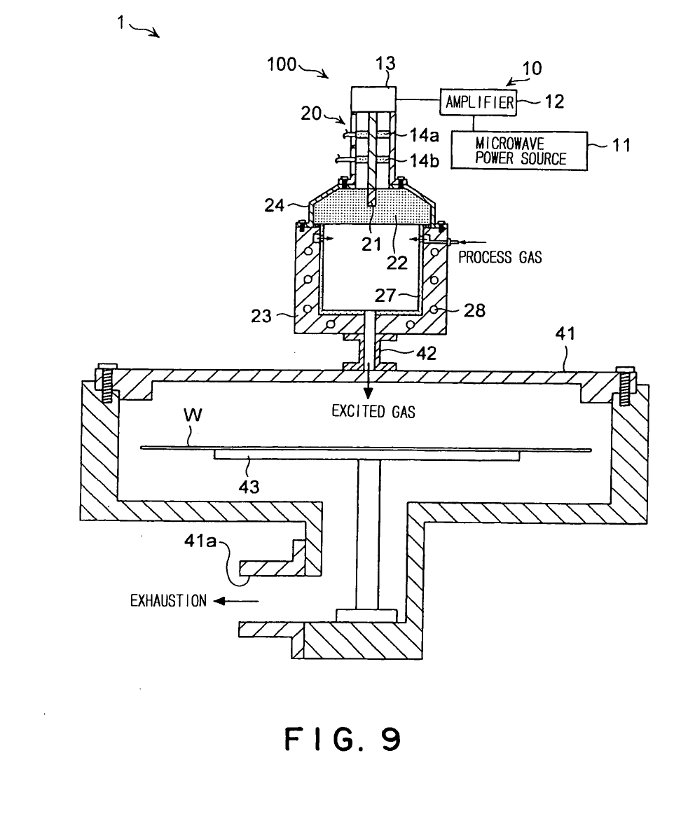

In the next place a plasma etching apparatus as a substrate processing apparatus comprising the plasma generating apparatus 100 described above for etching semiconductor wafers will be hereinafter explained. FIG. 9 is a cross-sectional view showing a schematic structure of a plasma etching apparatus 1. The plasma etching apparatus 1 has the plasma generating apparatus 100, a wafer processing chamber 41 which accommodates a wafer W, and a gas pipe 42 which connects the chamber 23 to the wafer processing chamber 41 and delivers the excited gas generated in the chamber 23 to the wafer processing chamber 41.

In the interior of the wafer processing chamber 41, a stage 43 is provided to mount a wafer W. The wafer processing chamber 41 has an openable/closable opening (not shown) for loading and unloading the wafer W, and the wafer W is loaded into the wafer processing chamber 41 by conveying means, not shown, and conversely the wafer W is unloaded from the wafer processing chamber 41 after plasma etching is completed. The excited gas produced in the plasma generating apparatus 100 is fed from the gas pipe 42 to the wafer processing chamber 41 to process the wafer W and then exhausted from an exhaust vent 41a provided in the wafer processing chamber 41.

In such plasma etching apparatus 1, the size of the plasma generating apparatus 100 can be reduced, and thus utility of the space above the wafer processing chamber 41 can be improved. Making efficient use of this, piping and wiring of every kind and a control device or the like can be placed, and the whole plasma etching apparatus 1 can be structured compactly as a result.

While the embodiments of the present invention have been explained, the present invention is not limited to the sole embodiments described above. For example, a coaxial line can replace the coaxial waveguide 20. Moreover, the present invention can be applicable to plasma processing, other than etching described herein, such as plasma CVD (film formation) and ashing. Furthermore, the plasma-processed substrates are not limited to semiconductor wafers but may be LCD substrates, glass substrates, ceramic substrates, etc.

### INDUSTRIAL APPLICABILITY

The present invention is suitable for various processing apparatus using plasma, such as an etching apparatus, plasma CVD apparatus, ashing apparatus, for example.

1. A plasma generating apparatus comprising:
a microwave generating apparatus for generating microwaves with a predetermined wavelength;
a coaxial waveguide having a coaxial structure comprising an inner tube and an outer tube, an antenna being attached to one end of said inner tube, for directing the microwaves generated by said microwave generating apparatus to said antenna;
a resonator composed of dielectric material for holding said antenna; and
a chamber in which a specific process gas is fed for plasma excitation, said chamber having an open surface, said resonator being placed on said open surface,
wherein said process gas is excited by the microwaves radiated from said antenna through said resonator into the interior of said chamber.

2. A plasma generating apparatus according to claim 1, wherein said antenna is a monopole antenna.

3. A plasma generating apparatus according to claim 2, wherein, when λa is a wavelength of the microwaves generated by said microwave generating apparatus, εr is a relative dielectric constant of said resonator, and λg is a wavelength of the microwaves inside said resonator obtained by dividing said wavelength λa by the square root of said relative dielectric constant εr (λg=λa/εr^{1/2}), said monopole antenna has a length of 23%-26% of said wavelength λg, and said resonator has a thickness of 50%-70% of said wavelength λg.

4. A plasma generating apparatus according to claim 1, wherein said antenna is a helical antenna.

5. A plasma generating apparatus according to claim 4, wherein, when λa is a wavelength of the microwaves generated by said microwave generating apparatus, εr is a relative dielectric constant of said resonator, and λg is a wavelength of the microwaves inside said resonator obtained by dividing said wavelength λa by the square root of said relative dielectric constant εr (λg=λa/εr^{1/2}), a thickness of said resonator, between the end of said helical antenna and a surface of said resonator on the side of said chamber is 25%-45% of said wavelength λg.

6. A plasma generating apparatus according to claim 1, wherein said antenna is a slot antenna.

7. A plasma generating apparatus according to claim 6, wherein, when λa is a wavelength of the microwaves generated by said microwave generating apparatus, εr is a relative dielectric constant of said resonator, and λg is a wavelength of the microwaves inside said resonator obtained by dividing said wavelength λa by the square root of said relative dielectric constant εr (λg=λa/εr^{1/2}), said resonator has a thickness of 25%-45% of said wavelength λg.

8. A plasma generating apparatus according to claim 1, wherein said microwave generating apparatus has a microwave power source, an amplifier for regulating output power of the microwaves which are output from said microwave power source, and an isolator for absorbing reflected microwaves which are returning to said amplifier after being output from said amplifier.

9. A plasma generating apparatus according to claim 1, comprising a plurality of said coaxial waveguide and said antenna, wherein said microwave generating apparatus has a microwave power source, a distributor for distributing the microwaves generated by said microwave power source to each of said coaxial waveguide and said antenna, a plurality of amplifiers for regulating output power of microwaves respectively which are output from said distributor, and a plurality of isolators for absorbing reflected microwaves which are returning to said plurality of amplifiers after being output from said plurality of amplifiers.

10. A plasma generating apparatus according to claim 9, further comprising a plasma control device for controlling said microwave generating apparatus, wherein microwaves are radiated from one or some of said plurality of antennas through said resonator into the interior of said chamber to excite said process gas and, after the plasma generation, microwaves are radiated from all of said plurality of antennas through said resonator into the interior of said chamber.

11. A plasma generating apparatus according to claim 1, wherein said resonator is composed of either quartz-type material, single-crystal-alumina-type material, polycrystalline-alumina-type material or aluminum-nitride-type material.

12. A plasma generating apparatus according to claim 1, wherein a corrosion protection member composed of quartz-type material, single-crystal-alumina-type material or polycrystalline-alumina-type material is applied on the inner surface of said chamber to prevent corrosion of said chamber.

13. A plasma generating apparatus according to claim 1, wherein said chamber has a jacket structure with cooling ability by flowing a coolant in the interior of the members constituting said chamber.

14. A plasma generating apparatus according to claim 1, wherein said chamber is a base-enclosed cylindrical member and has said open surface at one end, said base-enclosed cylindrical member having an exhaust vent in the bottom wall to discharge the gas excited by microwaves outwardly from said chamber and a gas discharge opening in the proximity of the open surface side of the side wall to discharge said process gas to the interior space.

15. A plasma generating apparatus according to claim 1, wherein a slug tuner that is slidable in a longitudinal direction of said coaxial waveguide is attached to said coaxial waveguide to perform impedance matching for said antenna.

16. A plasma generating method in a plasma generating apparatus comprising a plurality of antennas for radiating microwaves of a predetermined output level to a chamber in which a process gas is fed for plasma excitation, the method comprising the steps of:
generating plasma by radiating microwaves from one or some of said plurality of antennas into the interior of said chamber to excite said process gas; and
stabilizing the plasma by radiating microwaves from all of said plurality of antennas into the interior of said chamber after the plasma generation.

17. A remote plasma processing apparatus comprising:
a plasma generating apparatus for exciting a specific process gas by microwaves; and
a substrate processing chamber for accommodating a substrate and providing specific processing to said substrate by the excited gas generated by exciting said process gas in said plasma generating apparatus,
said plasma generating apparatus comprising:
a microwave generating apparatus for generating microwaves with a predetermined wavelength;
a coaxial waveguide having a coaxial structure comprising an inner tube and an outer tube, an antenna being attached to one end of said inner tube, for directing the microwaves generated by said microwave generating apparatus to said antenna;
a resonator composed of dielectric material for holding said antenna; and
a chamber in which a specific process gas is fed to be excited by the microwaves radiated from said antenna through said resonator for plasma excitation.
